(19) United States
(12) Patent Application Publication
(10) Pub. No.: US 2013/0320359 A1
(43) Pub. Date: Dec. 5, 2013

(54) HETEROGENEOUS STACK STRUCTURES WITH OPTICAL TO ELECTRICAL TIMING REFERENCE DISTRIBUTION

(71) Applicant: Klaus HUMMLER, Ballston Lake, NY (US)

(72) Inventor: Klaus HUMMLER, Ballston Lake, NY (US)

(73) Assignee: SEMATECH, INC., Albany, NY (US)

(21) Appl. No.: 13/487,694

(22) Filed: Jun. 4, 2012

(51) Int. Cl. H01L 23/48; H01L 31/12; H01L 31/02; H01L 27/144

(52) U.S. Cl. 257/80; 257/774; 257/443; 257/431; 257/E31.095; 257/E31.11; 257/E27.127; 257/E23.011

(57) ABSTRACT

A heterogeneous stack structure is provided which includes one or more optical signal-based chips and multiple electrical signal-based chips. The optical chip(s) and the electrical chip(s) are different layers of the stack structure, and the optical chip(s) includes optical signal paths extending at least partially laterally within the optical chip(s). Electrical signal paths are provided extending between and coupling the optical chip(s) and the electrical chips. The electrical signal paths include one or more through substrate vias (TSVs) through one or more electrical chips of the multiple electrical chips in the stack structure. In one embodiment, the optical chip(s) is configured laterally to locally distribute, via one or more paths of the electrical signal paths, a timing reference signal for one or more electrical chips in the stack. Conversion between optical and electrical signals within the stack structure occurs within the optical chip(s).

### BACKGROUND

Integrated circuits (ICs) form the basis for many electronic systems. Essentially, an integrated circuit (IC) includes a vast number of transistors and other circuit elements that are formed on a single semiconductor wafer or chip and are interconnected to implement a desired function. The complexity of these integrated circuits (ICs) requires the use of an ever-increasing number of linked transistors and other circuit elements.

Many modern electronic systems are created through the use of a variety of different integrated circuits; each integrated circuit (IC) performing one or more specific functions. For example, computer systems include at least one microprocessor and a number of memory chips. Conventionally, each of these integrated circuits (ICs) is formed on a separate chip, packaged independently and interconnected on, for example, a printed circuit board (PCB).

Three-dimensional integration of integrated circuits (ICs) may be employed to reduce the length of interconnections, and the corresponding wiring delay and coupling capacitance between wires, loss mechanisms, and other unwanted wire parasitics. Part of wire congestion in a two-dimensional spatial arrangement may originate with an inability to optimally place components to be connected. In comparison, a three-dimensional arrangement allows more possibilities for obtaining optimal placement of components and devices. As a further advantage, three-dimensional placement of components can facilitate a reduction in the overall size for the resultant package required to house the integrated circuits. Packaging may often be more expensive than the integrated circuits which the package encloses, and therefore, housing (for example) multiple integrated circuit chips in a single three-dimensional assembly can produce a cost advantage. One type of multichip package comprises a stack of semiconductor dies one upon the other, with the dies electrically interconnected using wire bond or perimeter tape connections along the edges of the dies. Stacking using wire bonding is in current use today in multifunction cell phones and digital cameras.

### BRIEF SUMMARY

The present invention relates, in one aspect, to a novel stack structure which includes at least one optical signal-based chip and multiple electrical signal-based chips. The at least one optical signal-based chip includes optical signal paths that extend at least partially laterally within the optical chip(s), and the multiple electrical signal-based chips and the at least one optical signal-based chip are different chips of the stack structure. Electrical signal paths couple the at least one optical signal-based chip and the multiple electrical signal-based chips, and conversion between optical and electrical signals within the stack structure occurs within the optical signal-based chip(s). At least one electrical signal path of the electrical signal paths coupling the optical signal-based chip(s) and the electrical signal-based chips comprises at least one through substrate via (TSV) through at least one electrical signal-based chip of the multiple electrical signal-based chips in the stack structure.

In another aspect, a stack structure is presented which includes at least one optical signal-based chip and multiple electrical signal-based chips. The at least one optical signal-based chip includes optical signal paths that extend at least partially laterally within the at least one optical signal-based chip, and the multiple electrical signal-based chips and the at least one optical signal-based chip are different chips of the stack structure. Electrical signal paths couple the multiple electrical signal-based chips and the at least one optical signal-based chip, and conversion between optical and electrical signals within the stack structure occurs within the at least one optical signal-based chip. Multiple electrical signal paths of the electrical signal paths coupling the at least one optical signal-based chip and the multiple electrical signal-based chips each include at least one through substrate via (TSV) through at least one electrical signal-based chip of the multiple electrical signal-based chips in the stack structure.

In a further aspect, a method is provided which includes: forming a stack structure, the forming comprising stacking at least one optical signal-based chip and at least one electrical signal-based chip, wherein optical signal paths extend at least partially laterally within the at least one optical signal-based chip, and the at least one optical signal-based chip and the at least one electrical signal-based chip are different chips of the stack structure; and wherein forming the stack structure comprises providing a plurality of vertical electrical signal paths coupling the at least one optical signal-based chip and the at least one electrical signal-based chip, and wherein conversion between optical and electrical signals within the stack structure occurs within the at least one optical signal-based chip, and at least one vertical electrical signal path of the plurality of vertical electrical signal paths comprises at least one through substrate via (TSV) through at least one electrical signal-based chip of the multiple electrical signal-based chips in the stack structure.

Additional features and advantages are realized through the techniques of the present invention. Other embodiments and aspects of the invention are described in detail herein and are considered a part of the claimed invention.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 depicts a cross-sectional elevational view of one embodiment of a stack structure comprising an optical signal-based chip and multiple electrical signal-based chips, in accordance with one or more aspects of the present invention;

FIG. 2 is a plan view of one exemplary embodiment of an optical signal-based chip of a stack structure, in accordance with one or more aspects of the present invention; and

FIG. 3 depicts one embodiment of a flow diagram of a design process which may be employed in design and manufacture of stack structures, in accordance with one or more aspects of the present invention.

### DETAILED DESCRIPTION

In three-dimensional technology, two or more layers of, for example, active CMOS circuitry may be stacked over one another. For example, a standard “thick” CMOS chip may be connected to a heat sink, while one or more “thinned” CMOS layers may be inserted between the thick chip and the package. These thin layers (on the order of tens of microns in thickness or less) may include through substrate vias (TSVs) to facilitate electrical connection between the layers within the stack. In general, a thinned layer can be placed in a 3D chip stack such that the back end of line (BEOL) faces the surface of the thick chip (“face-to-face” orientation), or such that the BEOL faces the back surface of the thick chip (“face-to-back” orientation).

In accordance with aspects of the present invention, one or more optical signal-based chips are incorporated into a three-dimensional stack structure, producing a hybrid or heterogeneous stack structure comprising both an optical signal-based chip(s) and multiple electrical signal-based chips, wherein the electrical signal-based chips may each comprise, for example, a semiconductor chip comprising electrical elements, such as resistors, diodes, transistors, etc., formed on or within a chip substrate. Note that, as used herein, the terms “within” or “on” can include “in”, “partially in”, “over”, etc., as appropriate for a particular implementation. Further, note for purposes of this application, that the term “substrate” may refer to a support upon which, within which, or partially within which, structures and/or devices may be formed.

The one or more optical signal-based chips of the stack structure may include optical elements, such as laser diodes, optical waveguides, detectors, etc., configured to perform (in one embodiment) as described herein. Advantageously, by providing separate optical signal-based and electrical signal-based chips, the number of process steps required to manufacture a particular chip (such as a CMOS chip) may be optimized for the function being implemented. That is, the number of process steps depend upon the function and the type of devices (or macros) that are being incorporated into the chip. Thus, the optical signal-based chip can be optimized for fabrication of optical elements, and the electrical signal-based chips can be optimized for fabrication of electrical elements.

Note that the stack structure and methods of fabrication thereof are described hereinbelow with reference to optical chips and electrical chips. A chip is commonly referred to as a die, or as an integrated circuit, but an integrated circuit may include additional components, such as a lead frame, bond wires and packaging. As used herein, an optical signal-based chip comprises optical elements and optical signal paths that extend at least partially laterally within the optical signal-based chip, and an electrical signal-based chip comprises electrical elements and electrical signal paths that extend at least partially laterally within the electrical signal-based chip.

While optical interconnects are currently used for system-to-system communication (such as a for back plane), they have not been widely implemented for on-board or on-chip communication. Obstacles to implementing on-chip optical networks include space, cost and yield constraints. Placing optical elements, such as waveguides, attenuators, modulators, detectors, light sources, etc., on the same semiconductor die as, for example, CMOS circuits, requires significant area, and processing of new materials which are not typically found in the semiconductor chip process flow. More particularly, building quality SiGe optical elements on the same wafer as CMOS circuits would be difficult and costly.

Generally stated, disclosed herein is a novel heterogeneous stack structure and method of fabrication, which comprises at least one optical signal-based chip and multiple electrical signal-based chips. Optical signal paths extend at least partially laterally within the at least one optical signal-based chip, and the optical signal-based chip and the electrical signal-based chips are different chips of the stack structure. Electrical signal paths extend between and couple the at least one optical signal-based chip and the multiple electrical signal-based chips, and significantly, conversion between optical and electrical signals within the stack structure occurs exclusively within the at least one optical signal-based chip.

Advantageously, at least one electrical signal path of the electrical signal paths coupling the optical signal-based chip and the electrical signal-based chips includes one or more through substrate vias (TSVs) through one or more chips in the stack structure. Note that, as used herein, through substrate vias may be understood, in the most general sense, as an electrical connection through a layer, such as a chip substrate, wherein the substrate may comprise silicon or other material. Through substrate vias, and fabrication methods therefor, are described in commonly assigned, co-pending application Ser. No. 13/469,494, entitled, “Semiconductor Structure with Buried Through Substrate Vias”, the entirety of which is hereby incorporated herein by reference. Depending on the implementation, through substrate vias may reside within one or more optical signal-based chips and/or one or more electrical signal-based chips in the stack structure.

By way of example, with such a stack structure, an optical signal-based chip of the stack may be configured to facilitate local distribution (via one or more paths of the electrical signal paths) of one or more instances of an electrical signal to one or more electrical signal-based chips of the stack. For example, the stack structure may be configured with a heterogeneous clock distribution network, wherein an optical signal-based chip is configured to distribute a timing reference signal to the electrical signal-based chip(s). One or more optical-to-electrical signal converters, detectors, etc., may be employed within the optical signal-based chip to facilitate conversion of an optical timing signal to an electrical timing signal for distribution via the electrical signal paths coupling the optical signal-based chip(s) and the electrical signal-based chip(s).

Further, in another embodiment, one or more electrical-to-optical signal converters may also be employed within the optical signal-based chip(s) to facilitate conversion of electrical signals back to optical signals. For example, in a timing network, there may be synchronization signals generated at one end of an electrical signal-based chip which will need to be propagated to the other end of the electrical chip. Employing the heterogeneous stack structure disclosed herein, these electrical signals could be converted to optical signals within the optical signal-based chip(s) for lateral propagation across the stack structure, with virtually no delay, and then be reconverted at the other side of the stack structure into electrical signals for return to the electrical signal-based chip(s).

Advantageously, the heterogeneous stack structures and methods disclosed herein may combine the advantages of three-dimensional chip stacking with through substrate vias (TSVs), along with the advantages of optical signaling for, for example, providing a package-internal timing reference signal. Note that, in addition to employing through substrate vias (TSVs), front-end-of-line (FEOL) and back-end-of-line (BEOL) vias and interconnect layers may be employed to electrically connect from, for example, an optical signal-based chip to one or more electrical signal-based chips, as well as through (for instance) an optical or electrical signal-based chip to one or more other optical or electrical signal-based chips.

Rather than intermixing optical and electrical signaling devices on the same chip, as might be employed in a system-on-chip (SOC) approach, disclosed herein is the provision of one or more dedicated optical signal-based chips within the stack structure that are vertically interconnected via multiple electrical signal paths, including via TSVs. The heterogeneous stack structure disclosed advantageously allows for fabrication of smaller chips, with dedicated process technology for the optical chip(s) and for the other chips (e.g., CMOS, but not limited to CMOS chips), which results in higher yields, lower costs, and higher performance.

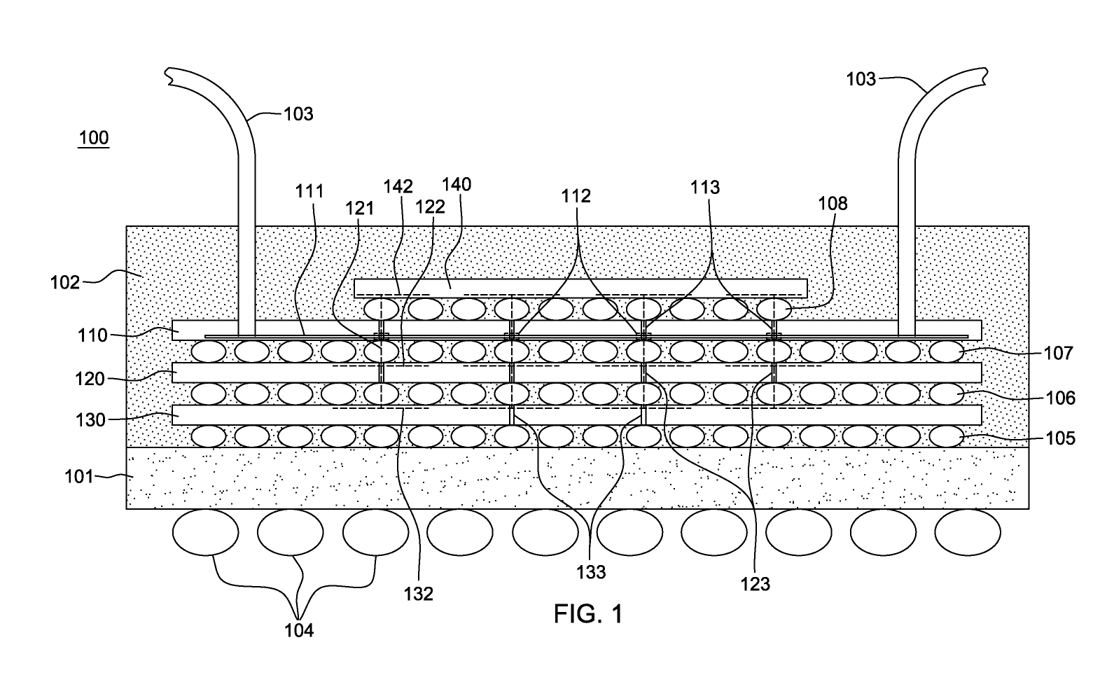

FIG. 1 depicts one embodiment of a packaged heterogeneous stack structure, generally denoted 100, in accordance with one or more aspects of the present invention. Stack structure 100 includes a substrate 101 and, by way of example, an encapsulant 102, which encapsulates multiple stacked chips of the stack structure 100 within the package. In this embodiment, stack structure 100 includes an optical signal-based chip 110 and multiple electrical signal-based chips 120, 130 & 140. Note with respect to this figure, that one or more of the chips in the stack may be of different size and/or configuration from one or more other chips in the stack. Further, note that the optical signal-based chip(s) may be located in any position within the stack, such as between electrical signal-based chips, or above or below electrical signal-based chips.

Package-level optical fiber connections 103 are provided to optical signal-based chip 110, and package-level electrical connections 104 are provided to the stack of chips, for example, via electrical interconnect (not shown) within substrate 101. Additionally, a plurality of chip-level electrical interconnects 105, 106 couple electrical signal-based chip 130 to substrate 101, and couple electrical signal-based chip 120 to electrical signal-based chip 130, respectively. In addition, chip-level electrical interconnects 107, 108 electrically connect optical signal-based chip 110 with the adjacent electrical signal-based chips 120, 140, respectively.

In the embodiment illustrated, optical signal-based chip 110 comprises optical elements, such as, by way of example, a plurality of laterally-spaced, optical-to-electrical signal converters 112 coupled to one or more laterally-extending optical signal paths 111 of optical signal-based chip 110. In one embodiment, the optical elements, such as the optical-to-electrical signal converters 112, are spaced laterally within the optical signal-based chip (at an active device side thereof) to facilitate local distribution vertically of a signal, such as a timing reference signal, to electrical elements of one or more of the electrical signal-based chips 120, 130 & 140. To accomplish this, optical-to-electrical signal converters 112 also electrically couple to vertically-extending electrical signal paths 121 vertically interconnecting optical signal-based chip 110 and the electrical signal-based chips 120, 130 & 140. As illustrated, locally laterally-extending signal paths 122, 132 & 142 may also be provided within electrical signal-based chips 120, 130 & 140, respectively, for distributing, for example, an electrical timing signal from optical signal-based chip 110 to selected circuitry (not shown) within one or more of electrical signal-based chips 120, 130 & 140. As noted, one or more of the electrical signal paths 121 may comprise or extend through one or more through substrate vias (TSVs) 123 & 133, through electrical signal-based chips 120 & 130 to, for example, electrically connect via chip-level interconnects 107, 106 & 105 to circuits of an active device layer within electrical signal-based chips 120 or 130, or even, for example, to electrical interconnect metallization on substrate 101 for connection therethrough to package-level electrical interconnects 104. Still further, one or more through substrate vias 113 may be provided through the one or more optical signal-based chip(s) 110 to, for example, facilitate electrical connection from the active device side of the optical signal-based chip to electrical signal-based chip 140, in this example.

Advantageously, optical-to-electrical signal converters 112 can be repeated and positioned within the optical signal-based chip 110 as needed to facilitate distributing locally within the electrical signal-based chip any desired signal, such as a timing reference signal. In this manner, global timing can be provided to the electrical signal-based chips 120, 130 & 140 via the optical signal-based chip 110, while significantly reducing power consumption and, for example, eliminating any need for electrical repeaters in order to distribute the signal.

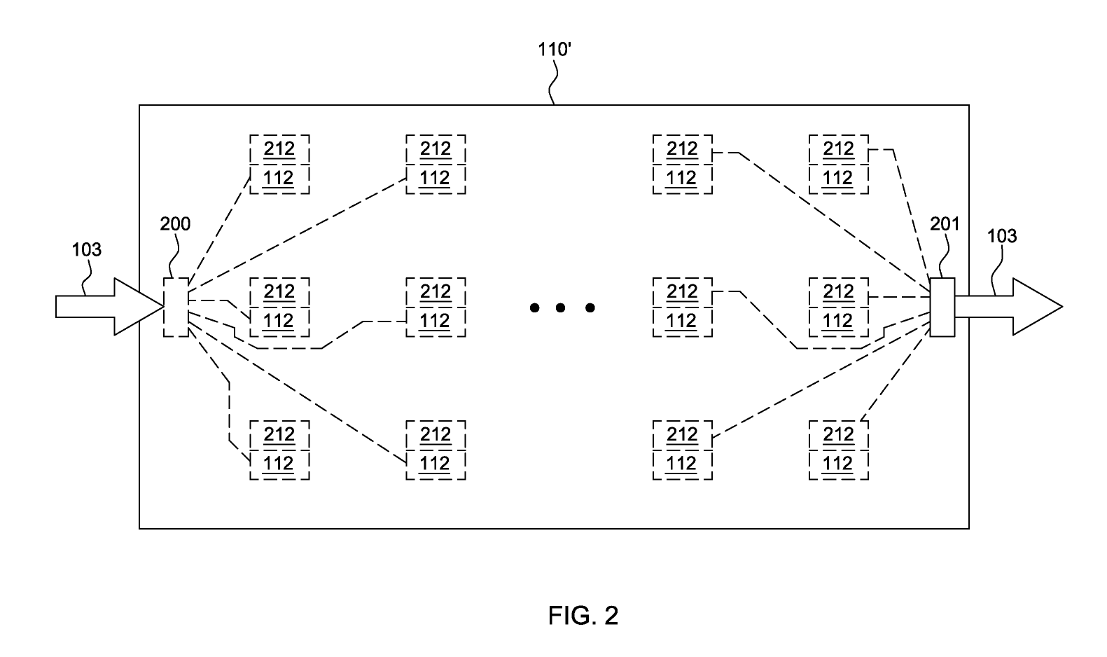

The optical signal-based chip may include various optical elements, such as one or more of external connections to optical fibers, light sources, modulators, attenuators, optical networks (waveguides), and other elements typically found in optical signal processing. FIG. 2 partially depicts one embodiment of an optical signal-based chip 110′ for a heterogeneous stack structure such as disclosed herein. In this embodiment, package-level optical fibers 103 connect via optical couplers 200, 201 to multiple optical-to-electrical signal converters 112 and to multiple electrical-to-optical signal converters 212, which facilitate conversion between optical and electrical signals within optical signal-based chip 110′. In one embodiment, this conversion between optical and electrical signals occurs exclusively within one or more of the optical signal-based chips of the stack structure. In this manner, circuits of the electrical signal-based chip(s) may, at least partially communicate optically internal or external the package, and/or as illustrated in FIG. 1, electrically (for example, via chip-level interconnects 105, 106, 107 & 108, interconnect layers within substrate 101, and package-level electrical connections 104 coupled to, for example, a printed circuit board (not shown)).

The plurality of laterally-spaced, optical-to-electrical signal converters 112 and the plurality of laterally-spaced, electrical-to-optical signal converters 212 may be spaced laterally across the optical signal-based chip 110 so as to align over respective portions of the electrical signal-based chip 120 (FIG. 1), and thereby facilitate local distribution of, for example, a timing reference signal from the optical signal-based chip to electrical elements within the electrical signal-based chip. Advantageously, providing the plurality of electrical-to-optical signal converters 212, laterally-spaced across the optical signal-based chip 110′, may facilitate, for example, propagation of synchronization signals generated locally at one end of the electrical signal-based chip laterally to another end of the electrical signal-based chip via the optical signal-based chip, which significantly reduces propagation delay of the electrical signal by converting the electrical signal locally to an optical signal, propagating the optical signal laterally across the optical signal-based chip, and reconverting the optical signal locally to an electrical signal for return vertically to the electrical signal-based chip(s). Note that, as used herein, “locally” refers to a relatively short length compared, for example, to the x-y dimensions of the particular chip.

Returning to FIG. 1, in one embodiment, at least some of the electrical interconnects 106, 107, 108 between the optical signal-based chip and the electrical signal-based chips may be vertically aligned to facilitate defining vertical electrical signal paths 321 coupling the optical signal-based chip and the multiple electrical signal-based chips. From the vertical electrical signal paths 121, local electrical signal paths 122, 132 & 142 may extend laterally into the active regions of the respective electrical signal-based chips 120, 130 & 140 to distribute, for example, a signal (such as a timing reference signal) provided from the optical signal-based chip via the vertical electrical signal paths 121 to electrical elements within the electrical signal-based chips. As noted, one or more package-level optical fiber 103 connections may be included to, for example, optically couple the resultant package to other packages or other systems.

Advantageously, in a multi-electrical signal-based chip configuration such as depicted in FIG. 1, through substrate vias can be employed in one or more of the electrical or optical signal-based chips in order to facilitate vertical electrical connection through the one or more chips. For example, in the embodiment of FIG. 1, through substrate vias 123 may be employed within electrical signal-based chip 120 to facilitate vertical electrical connection from optical signal-based chip 110 to electrical signal-based chip 130, and through substrate vias 133 may be employed within electrical signal-based chip 130 to, for example, facilitate vertical electrical connection between optical signal-based chip 110 to electrical interconnect on substrate 101. Note also that conversion between optical and electrical signals takes place exclusively within the optical signal-based chip(s), therefore eliminating any need for one or more optical elements in the non-optical chips, that is, in the electrical signal-based chips of the heterogeneous stack structure. As long as the optical-to-electrical or electrical-to-optical conversion is performed close to the vertical electrical signal paths coupling the chips, then the electrical signal path will be extremely short, allowing for ultra-high-speed and high-fidelity signal transmissions between the chips of the stack structure. By way of example, the signal path length may be equal to or less than the distance between repeaters in a traditional path implementation. The optical signal-based chip is able to laterally transmit signals extremely fast, with minimal latency over the entire lateral dimension of the optical chip, and via optical fiber, to other packages on (for example) a circuit board, or even to other systems. These advantages can be exploited to build, as described herein, a package-wide timing reference distribution network which is extremely accurate, can operate at very high speeds, and consumes a minimum amount of power since it does not require electrical repeaters. By aligning or positioning the optical-to-electrical converters (and optionally, the electrical-to-optical converters) within the optical signal-based chip vertically over or under an area of an electrical signal-based chip where a timing signal is to be distributed, minimum electrical signal lengths are obtained.

Distribution of timing references can be a significant problem with large system-on-chips (SOC), as well as within many systems, including systems-in-package (SIP). Timing references consume power, and inaccuracies in timing references reduce signal fidelity and usable bandwidth. Chip-to-chip communications typically have their own external timing reference requiring additional power in converting from chip-timing to chip-to-chip timing. On SOCs, across chip signal distribution requires a large number of repeaters, because of the resistive, inductive and capacitive parasitics associated with the electrical wiring. In contrast, in an optical chip, a global timing reference can be established and distributed with high precision, and without the use of repeaters.

As disclosed herein, such an optical timing reference can be established within the optical signal-based chip(s) of a stack structure and communicated through the entire package electrically, replacing on-chip clock trees and also chip-to-chip timing signals (e.g., data strobes in memory interfaces, etc.). The global optical timing reference is converted to a local electrical timing reference in close proximity to the vertical electrical signal path (which may comprise one or more through substrate vias), and distributed vertically to the electrical chips (or tiers) of the stack structure, as well as horizontally over short distances within each electrical signal-based chip, ideally without the use of repeaters. The lateral spacing of these conversion points on the optical signal-based chip(s) is determined by an overall optimization of the timing budget and space constraints for the optical-to-electrical conversion and electrical signal path placement.

Those skilled in the art will note from the above description that provided herein is a heterogeneous stack structure, wherein optical and electrical signaling are integrated in different chips of the stack structure. In one embodiment, through substrate via technology is combined with optical interconnects to provide an approach to realizing optical distribution of, for example, a timing reference signal and/or timing synchronization signals within one or more electrical signal-based chips of a stack structure. In implementation, the heterogeneous stack structure may comprise one or more dedicated optical signal-based chips, either above or below or in between one or more electrical signal-based chips of the stack structure. Conversion of optical signals to electrical signals occurs exclusively within the optical signal-based chip(s) using (for example) optical detectors, modulators, etc., built from SiGe, and transmission to electrical signal-based chips above or below the optical signal-based chips may be, at least in part, via one or more through substrate connections, such as through substrate vias. From the optical signal-based chip, external package-level optical fibers may be connected to couple the stack structure to one or more other packages or systems. Advantageously, optical-to-electrical conversion and electrical-to-optical conversion occurs close to the vertical electrical signal paths interconnecting the chips so as to minimize, or even eliminate, the need for repeaters or delays. Short vertical distribution and short lateral distribution of the signal electrically facilitates this implementation, as does using high-speed, optical-to-electrical conversion and/or electrical-to-optical conversion within the optical signal-based chip that is compatible with optical chip fabrication.

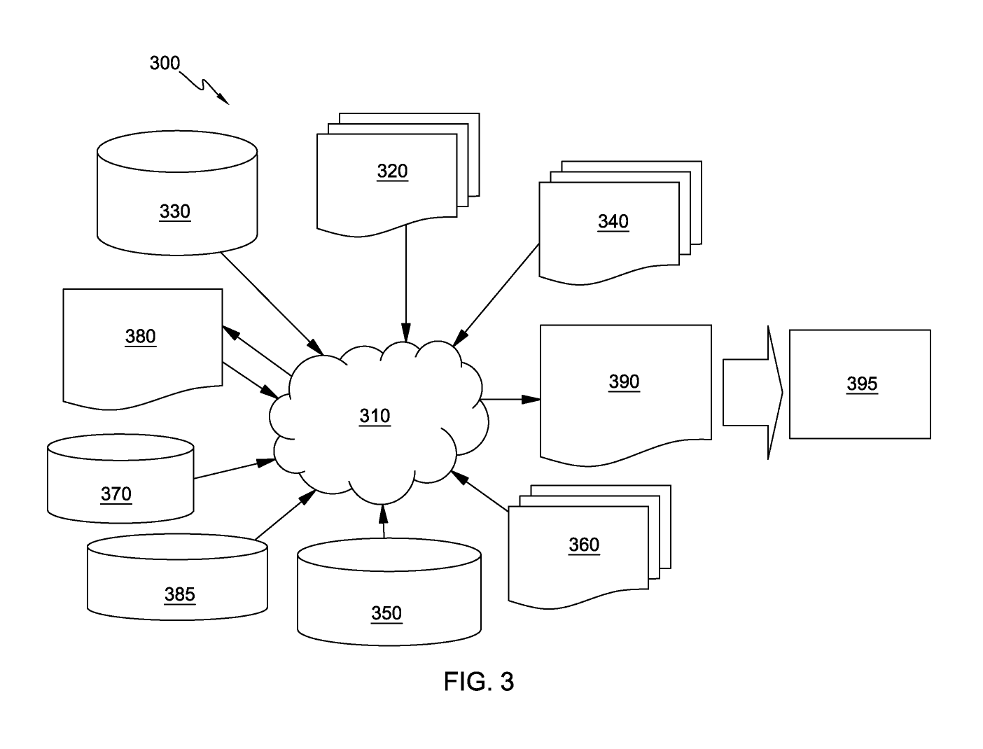

By way of further explanation, FIG. 3 illustrates multiple such design structures, including an input design structure 320 that is processed by a design process 310. Design structure 320 may be a logical simulation design structure, generated and processed by design process 310 to produce a logically, equivalent-functional representation of a hardware device. Design structure 320 may also, or alternately, comprise data and/or program instruction that, when processed by design process 310, generate a functional representation of the physical structure of a hardware device. Whether representing functional and/or structural design features, design structure 320 may be generated using electronic computer-aided design (ECAD), such as implemented by a core developer/designer. When encoded on a machine-readable data transmission, gate array, or storage medium, design structure 320 may be accessed and processed by one or more hardware and/or software modules within design process 310 to simulate or otherwise functionally represent an electronic component, circuit, electronic or logic module, apparatus, device or system, such as those shown in FIGS. 1-2. As such, design structure 320 may comprise files or other data structures, including human and/or machine-readable source code, compiled structures, and computer-executable code structures that, when processed by a design or simulation data processing system, functionally simulate or otherwise represent circuits or other levels of hardware logic design. Such data structures may include hardware-description language (HDL), design entities, or other data structures conforming to and/or compatible with lower-level HDL design languages, such as Verilog and VHDL, and/or higher-level design languages, such as C or C++.

Design process 310 may employ and incorporate hardware and/or software modules for synthesizing, translating, or otherwise processing a design/simulation functional equivalent of the components, circuits, devices or logic structures shown in FIGS. 1-23 to generate a netlist 380, which may contain design structures, such as design structure 320. Netlist 380 may comprise, for example, compiled or otherwise processed data structures representing a list of wires, discrete components, logic gates, control circuits, I/O devices, models, etc. that describes the connections to other elements and circuits in an integrated circuit design. Netlist 380 may be synthesized using an interactive process in which netlist 380 is re-synthesized one or more times, depending on design specifications and parameters for the device. As with other design structure types described herein, netlist 380 may be recorded on a machine-readable data storage medium, or programmed into a programmable gate array. The medium may be a non-volatile storage medium, such as a magnetic or optical disk drive, a programmable gate array, a compact flash, or other flash memory. Additionally, or in the alternative, the medium may be a system cache memory, buffer space, or electrically or optically conductive devices and materials on which data packets may be transmitted and intermediately stored via the Internet, or other networking suitable means.

Design process 310 may include hardware and software modules for processing a variety of input data structure types, including netlist 380. Such data structure types may reside, for example, within library elements 330 and include a set of commonly used elements, circuits, and devices, including modules, layouts, and symbolic representations, for a given manufacturing technology (e.g., different technology nodes, 32 nm, 45 nm, etc.). The data structure types may further include design specifications 340, characterization data 350, verification data 360, design rules 370, and test data files 385, which may include input test patterns, output test results, and other testing information. Design process 310 may further include, for example, standard mechanical design processes, such as stress analysis, thermal analysis, mechanical event simulation, process simulations for operations, such as casting, molding, and die press forming, etc. One of ordinary skill in the art of mechanical design can appreciate the extent of possible mechanical design tools and applications used in design process 310, without deviating from the scope and spirit of the invention. Design process 310 may also include modules for performing standard circuit design processes, such as timing analysis, verification, design rule checking, place and route operations, etc.

Design process 310 employs and incorporates logical and physical design tools, such as HDL, compilers and simulation module build tools to process design structure 320 together with some or all of the depicted supporting data structures, along with any additional mechanical design of data (if applicable), to generate a second design structure 390. Design structure 390 resides on a storage medium or programmable gate array in a data format used for the exchange of data of mechanical devices and structures (e.g., information stored in an IGES, DXF, Parasolid XT, JT, DRG, or any other suitable format for storing or rendering such mechanical design structures). Similar to design structure 320, design structure 390 may comprise one or more files, data structures, or other computer-encoded data or instructions that reside on transmission or data storage media, and that when processed by an ECAD system, generate a logically or otherwise functionally-equivalent form of one or more of the embodiments of the invention. In one embodiment, design structure 390 may comprise a compiled, executable HDL simulation model that functionally simulates the processes and devices shown in FIGS. 1-2.

Design structure 390 may also employ a data format used for the exchange of layout data of integrated circuits and/or symbolic data format (e.g., information stored in a GDSII (GDS2), GL1, OASIS, map files, or any other suitable format for storing such design data structures). Design structure 390 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure, such as described above and shown in FIGS. 1-2. Design structure 390 may then proceed to stage 395, where, for example, design structure 390 proceeds to tape-out, is released to manufacturing, is released to a mask house, is sent to another design house, is sent back to the customer, etc.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention.

What is claimed is:

1. A stack structure comprising:
at least one optical signal-based chip, wherein optical signals paths extend at least partially laterally within the at least one optical signal-based chip;
multiple electrical signal-based chips, the multiple electrical signal-based chips and the at least one optical signal-based chip being different chips of the stack structure, wherein electrical signal paths couple the at least one optical signal-based chip and the multiple electrical signal-based chips, and conversion between optical and electrical signals within the stack structure occurs within the at least one optical signal-based chip; and
wherein at least one electrical signal path of the electrical signal paths coupling the at least one optical signal-based chip and the multiple electrical signal-based chips comprises at least one through substrate via (TSV) through at least one electrical signal-based chip of the multiple electrical signal-based chips in the stack structure.

2. The stack structure of claim 1, wherein the at least one optical signal-based chip is configured to facilitate locally distributing, via multiple paths of the electrical signal paths, multiple instances of a signal to at least one electrical signal-based-chip of the multiple electrical signal-based chips.

3. The stack structure of claim 1, wherein the at least one optical signal-based chip is configured to facilitate locally distributing, via multiple paths of the electrical signal paths, a timing reference signal for at least one electrical signal-based chip of the multiple electrical signal-based chips.

4. The stack structure of claim 3, wherein the at least one optical signal-based chip comprises a plurality of optical-to-electrical signal converters spaced at least partially laterally within the at least one optical signal-based chip, the plurality of optical-to-electrical signal converters being coupled within the at least one optical signal-based chip to facilitate local distribution within the at least one electrical signal-based chip, via the multiple paths of the electrical signal paths, of the timing reference signal, wherein the timing reference signal is converted within the at least one optical signal-based chip from an optical signal.

5. The stack structure of claim 4, wherein the at least one optical signal-based chip further comprises a plurality of electrical-to-optical signal converters spaced at least partially laterally within the at least one optical signal-based chip, the plurality of electrical-to-optical signal converters being coupled to at least some paths of the electrical signal paths to facilitate distribution of a synchronization signal within the at least one electrical signal-based chip via conversion within the at least one optical signal-based chip to an optical synchronization signal, and subsequent reconversion to an electrical synchronization signal for return to the at least one electrical signal-based chip.

6. The stack structure of claim 1, wherein the at least one optical signal-based chip further comprises at least one optical-to-electrical signal converter disposed therein coupled to at least one optical signal path of the optical signal paths of the optical signal-based chip and to at least one electrical signal path of the electrical signal paths coupling the at least one optical signal-based chip and the multiple electrical signal-based chips, the at least one optical-to-electrical signal converter converting an optical signal of the at least one optical signal path to an electrical signal of the at least one electrical signal path.

7. The stack structure of claim 1, wherein the electrical signal paths coupling the at least one optical signal-based chip and the multiple electrical signal-based chips comprise a plurality of vertical electrical signal paths within the stack structure, the plurality of vertical electrical signal paths utilizing a plurality of through substrate vias (TSVs).

8. The stack structure of claim 1, wherein the stack structure comprises one or more package-level optical fiber connections to the at least one optical signal-based chip.

9. The stack structure of claim 1, wherein one electrical signal path of the electrical signal paths coupling the at least one optical signal-based chip and the multiple electrical signal-based chips comprises multiple through substrate vias (TSVs) through the multiple electrical signal-based chips, each through substrate via of the multiple through substrate vias facilitating electrical connection through a different electrical signal-based chip of the multiple electrical signal-based chips.

10. A stack structure comprising:
at least one optical signal-based chip, wherein optical signal paths extend at least partially laterally within the at least one optical signal-based chip;
multiple electrical signal-based chips, the multiple electrical signal-based chips and the at least one optical signal-based chip being different chips of the stack structure, wherein electrical signal paths couple the at least one optical signal-based chip and the multiple electrical signal-based chips, and conversion between optical and electrical signals within the stack structure occurs within the at least one optical signal-based chip; and
wherein multiple electrical signal paths of the electrical signal paths coupling the at least one optical signal-based chip and the multiple electrical signal-based chips each comprise at least one through substrate via (TSV) through at least one electrical signal-based chip of the multiple electrical signal-based chips in the stack structure.

11. The stack structure of claim 10, wherein a first electrical signal-based chip of the multiple electrical signal-based chips is disposed in the stack structure between a second electrical signal-based chip of the multiple electrical signal-based chips and an optical signal-based chip of the at least one optical signal-based chip, and wherein the multiple signal paths of the electrical signal paths comprise a plurality of through substrate vias (TSVs) through the first electrical signal-based chip, the plurality of through substrate vias facilitating vertical electrical connection between the second electrical signal-based chip and the optical signal-based chip through the first electrical signal-based chip.

12. The stack structure of claim 10, wherein the at least one optical signal-based chip is configured, at least in part, to facilitate locally distributing, via multiple paths of the electrical signal paths, multiple instances of a signal to at least one electrical signal-based chip of the multiple electrical signal-based chips in the stack structure.

13. The stack structure of claim 10, wherein the at least one optical signal-based chip is configured, at least in part, to facilitate locally distributing, via multiple paths of the electrical signal paths, a timing reference signal for at least one electrical signal-based chip of the multiple electrical signal-based chips in the stack structure.

14. The stack structure of claim 13, wherein the at least one optical signal-based chip comprises a plurality of optical-to-electrical signal converters spaced at least partially laterally within the at least one optical signal-based chip, the plurality of optical-to-electrical converters being coupled within the at least one optical signal-based chip to facilitate local distribution within the at least one electrical signal-based chip, via the multiple paths of the electrical signal paths, of the timing reference signal, wherein the timing reference signal is converted within the at least one optical signal-based chip from an optical signal.

15. The stack structure of claim 10, wherein the at least one optical signal-based chip comprises at least one optical-to-electrical signal converter disposed therein coupled to at least one optical signal path of the optical signal paths of the at least one optical signal-based chip and to at least one electrical signal path of the electrical signal paths coupling the at least one optical signal-based chip and the multiple electrical signal-based chips, the at least one optical-to-electrical signal converter converting an optical signal of the at least one optical signal path to an electrical signal of the at least one electrical signal path.

16. The stack structure of claim 10, wherein the electrical signal paths coupling the at least one optical signal-based chip and the multiple electrical signal-based chips comprise a plurality of vertical electrical signal paths within the stack structure, the plurality of vertical electrical signal paths comprising a plurality of through substrate vias (TSVs).

17. A method comprising:
forming a stack structure, the forming comprising stacking at least one optical signal-based chip and multiple electrical signal-based chips, wherein optical signal paths extend at least partially laterally within the at least one optical signal-based chip, and the at least one optical signal-based chip and the multiple electrical signal-based chips are different chips of the stack structure; and
wherein forming the stack structure comprises providing a plurality of vertical electrical signal paths coupling the at least one optical signal-based chip and the multiple electrical signal-based chips, and wherein conversion between optical and electrical signals within the stack structure occurs within the at least one optical signal-based chip, and at least one vertical electrical signal path of the plurality of vertical electrical signal paths comprises at least one through substrate via (TSV) through at least one electrical signal-based chip of the multiple electrical signal-based chips in the stack structure.

18. The method of claim 17, wherein the at least one optical signal-based chip is configured to facilitate locally distributing, via multiple paths of the plurality of vertical electrical signal paths, multiple instances of a signal to at least one electrical signal-based chip of the multiple electrical signal-based chips in the stack structure.

19. The method of claim 17, wherein the at least one optical signal-based chip is configured to facilitate locally distributing, via multiple paths of the plurality of vertical electrical signal paths, a timing reference signal for at least one electrical signal-based chip of the multiple electrical signal-based chips in the stack structure.

20. The method of claim 17, wherein multiple electrical signal paths of the plurality of electrical signal paths coupling the at least one optical signal-based chip and the multiple electrical signal-based layers each comprise at least one through substrate via (TSV) through at least one electrical signal-based chip of the multiple electrical signal-based chips.
